(19) United States
(12) Patent Application Publication
(10) Pub. No.: US 2013/0011556 A1
(43) Pub. Date: Jan. 10, 2013

(54) CRUCIBLE, VAPOR DEPOSITION SYSTEM AND METHOD USING THE CRUCIBLE

(75) Inventor: JUIN-HONG LIN, Tu-Cheng (TW)

(73) Assignee: HON HAI PRECISION INDUSTRY CO., LTD., Tu-Cheng (TW)

(21) Appl. No.: 13/248,036

(22) Filed: Sep. 29, 2011

(30) Foreign Application Priority Data
Jul. 7, 2011 (TW) 100124128

(51) Int. Cl. C23C 16/448

(52) U.S. Cl. 427/248.1; 118/724

(57) ABSTRACT

A crucible includes a main body and a cover. The main body includes a first end surface, an opposite second end surface, a hollow part and a solid part. The hollow part and the solid part extend from the first end surface to the second end surface. The hollow part defines a receiving space. The first end surface defines an opening communicating with the receiving space, and includes a step positioned between the hollow part and the solid part. The solid part includes a heat end adjacent to the step. The heat end is heated by an electro-beam. The cover covers the opening, and defines a number of gas holes. The main body and the cover are made of thermal conductive refractory material.

### BACKGROUND

1. Technical Field

The present disclosure relates to a vapor deposition system and method, and a crucible used in the system and method.

2. Description of Related Art

In a vapor deposition system, a thermal resistor or an electron gun is usually used to heat and vaporize coating material. When heated by the thermal resistor, the coating material may chemically react with the thermal resistor to produce impurities. When using the electron gun to heat the coating material, the quality is effected as the coating material usually cannot be heated evenly.

Therefore, it is desirable to provide a crucible, a vapor deposition system and a vapor deposition method, which can overcome the limitations described.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a schematic, isometric view of a crucible according to an embodiment of the present disclosure.

FIG. 2 is an exploded view of the crucible of FIG. 1.

FIG. 3 is a cross-sectional view of the crucible of FIG. 1.

FIG. 4 is a cross-sectional view of a vapor deposition system according to an embodiment.

FIG. 5 is a flow chart of a vapor deposition method according to an embodiment.

### DETAILED DESCRIPTION

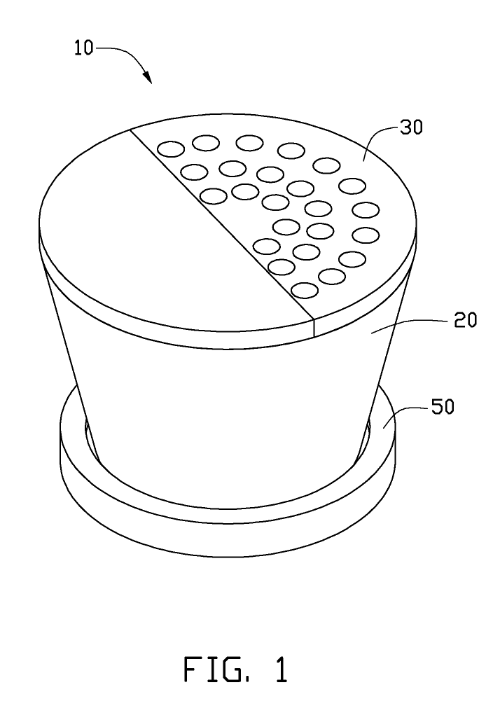

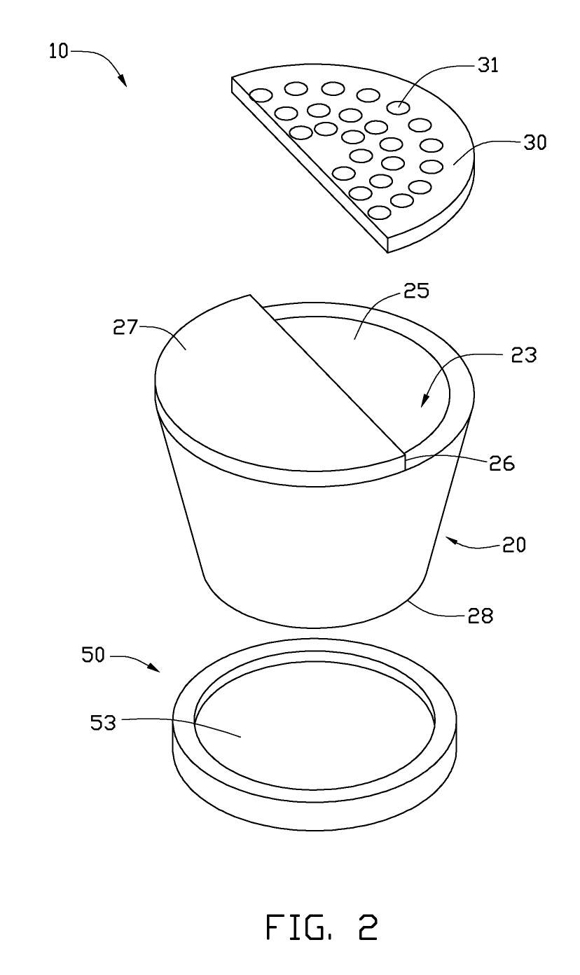

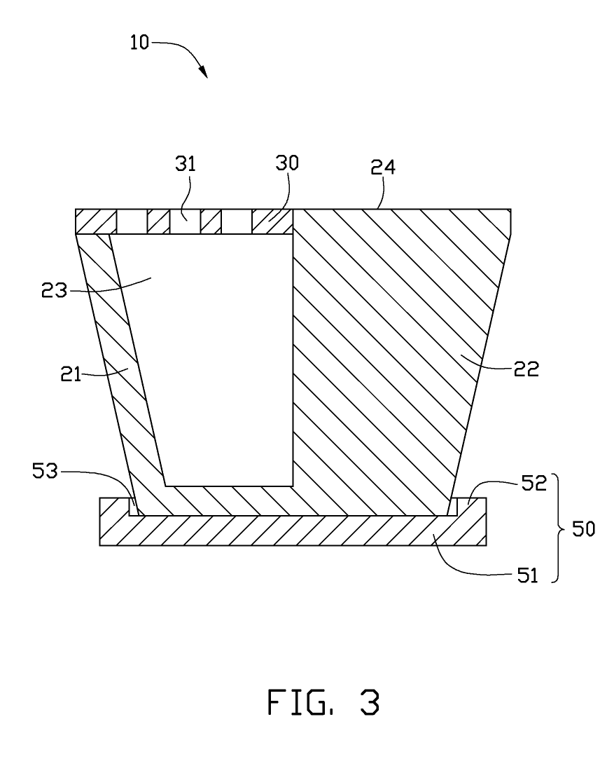

Referring to FIGS. 1 to 3, a crucible 10 according to an embodiment is disclosed. The crucible 10 includes a main body 20, a cover 30, and a thermal isolation dish 50.

The main body 20 includes an end surface 24 and an opposite end surface 28. The main body 20 further includes a hollow part 21 and a solid part 22 extending respectively from the end surface 24 to the end surface 28. The hollow part 21 defines a receiving space 23. The end surface 24 defines an opening 25 communicating with the receiving space 23. The end surface 24 is a stepped surface and includes a step 26. The step 26 is positioned between the hollow part 21 and the solid part 22. The solid part 22 is higher than the hollow part 21 at the end surface 24. The solid part 22 includes a heat end 27 positioned on the end surface 24. The sectional surface of the hollow part 21, the solid part 22, and the receiving space 23 are parallel to the end surface 24 and are all semi-circular shaped.

The cover 30 is semi-circular shaped, and defines a number of gas holes 31. The scale of the cover 30 is substantially equal to that of a cross-section of the hollow part 21 at the end surface 24. The height of the cover 30 is substantially equal to that of the step 26. The cover 30 covers the opening 25 and is supported by the hollow part 21.

The main body 20 and the cover 30 are made of thermally conductive refractory material, such as tungsten, molybdenum, or platinum.

The thermal isolation dish 50 includes a bottom wall 51 and an enclosed sidewall 52 extending from the bottom wall 51. The sidewall 52 defines an opening 53 opposite to the bottom wall 51. The size of the opening 53 is bigger than that of the end surface 28 of the main body 20 so that the main body 20 can be put in the thermal isolation dish 50. The thermal isolation dish 50 is made of thermal insulating refractory material, such as porcelain or graphite.

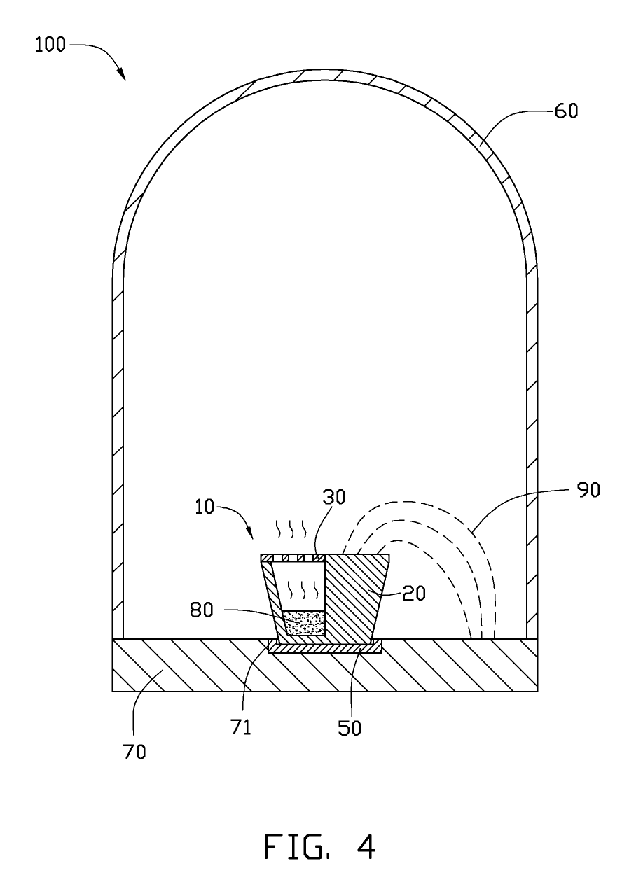

Referring to FIG. 4, a vapor deposition system 100 according to an embodiment is disclosed. The vapor deposition system 100 includes a housing 60, an electron gun seat 70, and the crucible 10. The electron gun seat 70 is mounted in the housing 60. The electron gun seat 70 defines a depression 71. The shape and scale of the depression 71 are substantially the same as those of the thermal isolation dish 50. The thermal isolation dish 50 is received in the depression 71, and the main body 20 is received in the thermal isolation dish 50. In this way, the main body 20 does not make contact with the electron gun seat 70.

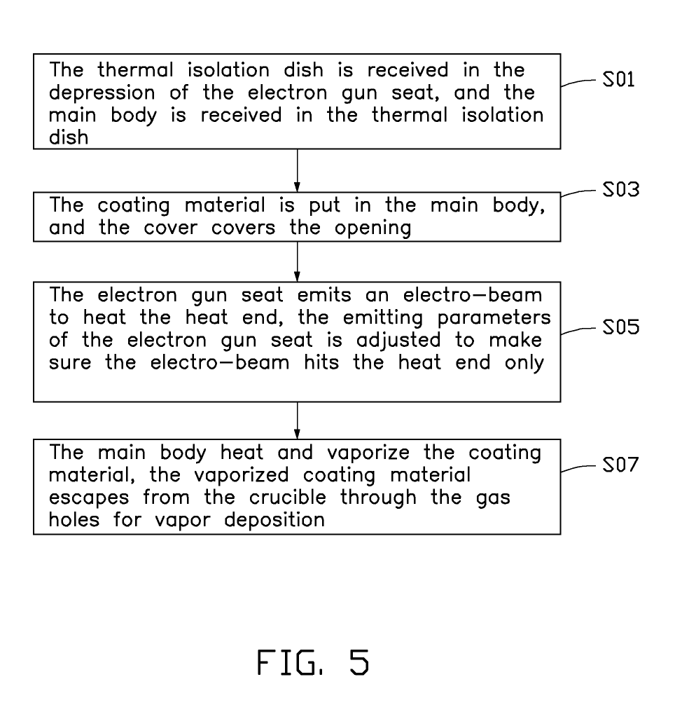

Referring to FIG. 5, a vapor deposition method according to an embodiment is disclosed. The vapor deposition method includes the following steps,

In step S01, the thermal isolation dish 50 is received in the depression 71 of the electron gun seat 70, and the main body 20 is received in the thermal isolation dish 50, the main body 20 does not contact with the electron gun seat 70.

In step S03, the coating material 80 is put in the receiving space 23 of the main body 20, and the cover 40 covers the opening 25.

In step S05, the electron gun seat 70 emits an electro-beam 90, the electro-beam 90 is guided by a magnetic field and hits the heat_end 27 to heat the solid part 22. The magnetic field and the emitting parameters of the electron gun seat 70 are adjusted to make sure the electro-beam 90 can hit the heat end 27 only. The operation of the electron gun seat 70 is familiar to one of ordinary skill in the art, thus, a detailed description is omitted here.

In step S07, the solid part 22 transmits heat to the hollow part 21, the main body 20 heat and vaporize the coating material 80, the vaporized coating material 80 escapes from the crucible 10 through the gas holes 31 of the cover 30 for vapor deposition.

It will be understood that the above particular embodiments are shown and described by way of illustration only. The principles and the features of the present disclosure may be employed in various and numerous embodiments thereof without departing from the scope of the disclosure. The above-described embodiments illustrate the scope of the disclosure but do not restrict the scope of the disclosure.

What is claimed is:

1. A crucible comprising:
a main body comprising:
a first end surface and an opposite second end surface; and
a hollow part and a solid part extending from the first end surface to the second end surface respectively, the hollow part defining a receiving space, the first end surface defining an opening communicating with the receiving space, and comprising a step positioned between the hollow part and the solid part, the solid part comprising a heat end adjacent to the step, the heat end configured for being heated by an electro-beam; and
a cover supported by the main body and covering the opening, the cover defining a number of gas holes communicating with the receiving space; wherein
the main body and the cover are made of thermal conductive refractory material.

2. The crucible of claim 1, further comprising a thermal isolation dish made of thermal insulating refractory material, the thermal isolation dish supporting the main body.

3. The crucible of claim 2, wherein the thermal isolation dish is made of material selected from the group consisting of: porcelain and graphite.

4. The crucible of claim 1, wherein the main body and the cover are made of material selected from the group consisting of: tungsten, molybdenum, and platinum.

5. A vapor deposition system comprising:
a housing;
an electron gun seat mounted in the housing, and defining a depression; and
a crucible comprising:
a thermal isolation dish received in the depression;
a main body positioned on the thermal isolation dish, and comprising:
a first end surface and an opposite second end surface; and
a hollow part and a solid part extending from the first end surface to the second end surface respectively, the hollow part defining a receiving space, the first end surface defining an opening communicated with the receiving space, and comprising a step positioned between the hollow part and the solid part, the solid part comprising a heat end adjacent to the step, the heat end configured for being heated by an electro-beam; and
a cover supported by the main body and covering the opening, the cover defining a number of gas holes communicating with the receiving space; wherein
the main body and the cover are made of thermal conductive refractory material.

6. The vapor deposition system of claim 5, wherein the main body and the cover are made of material selected from the group consisting of: tungsten, molybdenum, and platinum.

7. The vapor deposition system of claim 5, wherein the thermal isolation dish is made of material selected from the group consisting of: porcelain and graphite.

8. A vapor deposition method, comprising steps of:
providing a crucible, the crucible comprising:
a main body comprising:
a first end surface and an opposite second end surface; and
a hollow part and a solid part extending from the first end surface to the second end surface respectively, the hollow part defining a receiving space, the first end surface defining an opening communicating with the receiving space, and comprising a step positioned between the hollow part and the solid part, the solid part comprising a heat end adjacent to the step; and
a cover defining a number of gas holes, both of the main body and the cover made of thermal conductive refractory material;
putting coating material in the receiving space; and
covering the opening by using the cover, with the cover supported by the main body and the gas holes communicating with the receiving space;
emitting an electro-beam to heat the heat end such that the main body is heated to vaporize the coating material to escape out of the crucible through the gas holes.

9. The vapor deposition method of claim 8, wherein the crucible comprises a thermal isolation dish made of thermal insulating refractory material, the thermal isolation dish supports the main body.
